(19) United States
(12) Patent Application Publication
(10) Pub. No.: US 2025/0081802 A1
(43) Pub. Date: Mar. 6, 2025

(54) PACKAGE STRUCTURE, PREPARATION METHOD FOR PACKAGE STRUCTURE, AND DISPLAY PANEL

(71) Applicant: HKC CORPORATION LIMITED, Baoan District (CN)

(72) Inventors: Yao LI, Shenzhen (CN); Junfeng XIE, Shenzhen (CN)

(21) Appl. No.: 18/817,607

(22) Filed: Aug. 28, 2024

(30) Foreign Application Priority Data
Aug. 31, 2023 (CN) 202311129722.2

(51) Int. Cl. H10K 59/70; B01J 21/18; B01J 31/04; B01J 35/40; B01J 35/50; H10K 59/80; H10K 77/00

(52) U.S. Cl. CPC H10K 59/70; B01J 21/18; B01J 31/04; B01J 35/40; B01J 35/50; H10K 59/873; H10K 59/8731; H10K 77/00

(57) ABSTRACT

A package structure, a preparation method for the package structure, and a display panel are provided. The package structure includes a first inorganic layer, a photocatalytic layer, and a second inorganic layer that are sequentially stacked, where the photocatalytic layer includes a photocatalytic material and a co-catalyst. The photocatalytic material and the co-catalyst are used cooperatively to catalyze the decomposition of water vapor, the photocatalytic material includes graphitic carbon nitride (g-C3N4) particles, and the co-catalyst includes perylene tetracarboxylic acid (PTA). The photocatalytic layer possesses high catalytic efficiency and excellent stability. In the case where cracks are generated at the package structure, water vapor invading through the cracks is decomposed and consumed through an oxidation-reduction reaction, and then decomposition products are respectively discharged.

### CROSS-REFERENCE TO RELATED APPLICATIONS

This application claims priority under 35 U.S.C. § 119(a) to Chinese Patent Application No. 202311129722.2, filed Aug. 31, 2023, the entire disclosure of which is incorporated herein by reference.

### TECHNICAL FIELD

The present disclosure relates to the field of display technology, in particular, to a package structure, a preparation method for the package structure, and a display panel.

### BACKGROUND

Organic light emitting diode (OLED) is becoming increasingly mature in mass production due to advantages such as having a surface light source, cold light, low energy-consumption, fast response, flexibility, ultra-thinness, and low cost. However, an organic light-emitting layer in an OLED device has poor stability and is extremely sensitive to water, oxygen and heat. Therefore, packaging technology for the organic light-emitting layer is of highly significance. In the case where the OLED device is a flexible and bendable screen, a package layer of the OLED device is prone to crack as the screen may undergo multiple bending deformations. Cracks will accelerate the aging of the organic light-emitting layer, and thus a strictly packaging is needed, so as to prolong the service life and improve stability.

Currently, common packaging technology focuses on improving the sealing performance of the package layer to further improve the ability of isolating water vapor, and is usually unable to cope with or use absorption materials to absorb water vapor and oxygen that have already entered the package layer. In actual application, the screen may be exposed in extreme environments, for example, in an environment with high humidity during a reliability test. In this case, to a certain extent, water vapor intrusion is more likely to occur than oxygen intrusion. Moreover, in the case where cracks are generated, how to further reduce further intrusion of water vapor has become the key in prolonging the service life of bendable screens.

### SUMMARY

In a first aspect, the disclosure provides a package structure, where the package structure includes a first inorganic layer, a photocatalytic layer, and a second inorganic layer that are sequentially stacked. The photocatalytic layer includes a photocatalytic material and a co-catalyst. The photocatalytic material and the co-catalyst are used cooperatively to catalyze the decomposition of water vapor, the photocatalytic material includes graphitic carbon nitride (g-C₃N₄) particles, and the co-catalyst includes perylene tetracarboxylic acid (PTA).

In a second aspect, the disclosure provides a preparation method for a package structure. The preparation method includes the following. Form a first inorganic layer. Form a photocatalytic layer on a side of the first inorganic layer, where the photocatalytic layer includes a photocatalytic material and a co-catalyst, where the photocatalytic material and the co-catalyst are used cooperatively to catalyze the decomposition of water vapor, the photocatalytic material includes g-C₃N₄ particles, and the co-catalyst includes PTA. Form a second inorganic layer on a surface of the photocatalytic layer facing away from the first inorganic layer.

In a third aspect, the disclosure provides a display panel, which includes a light-emitting layer and the package structure. The light-emitting layer has a light-emitting surface configured to emit light. The package structure covers the light-emitting surface of the light-emitting layer, and the first inorganic layer is closer to the light-emitting layer than the second inorganic layer.

### BRIEF DESCRIPTION OF THE DRAWINGS

In order to describe technical solutions in the related art or embodiments of the disclosure more clearly, the following will give a brief introduction to the accompanying drawings required for describing the related art or embodiments. Apparently, the accompanying drawings hereinafter described are merely some embodiments of the disclosure. Based on these drawings, those of ordinary skill in the art can also obtain other drawings without creative effort.

FIG. 1 is a schematic view of a package structure provided in a comparative embodiment of the disclosure.

FIG. 2 is a schematic diagram illustrating a catalytic principle of a photocatalytic material provided in embodiments of the disclosure.

FIG. 3 is a schematic cross-sectional structural view of a package structure provided in embodiments of the disclosure.

FIG. 4 is a schematic structural view of a nanowire provided in embodiments of the disclosure.

FIG. 5 is a schematic structural view of a display apparatus and a display panel provided in embodiments of the disclosure.

FIG. 6 is a schematic cross-sectional structural view of the display panel provided in FIG. 5, taken along line A-A.

FIG. 7 is a schematic structural view of a cracked package structure provided in embodiments of the disclosure.

FIG. 8 is a schematic view illustrating a working principle of a package structure provide in embodiments of the disclosure.

FIG. 9 is a partially schematic structural view of a photocatalytic layer provided in embodiments of the disclosure.

FIG. 10 is a flow chart of a method for preparing a package structure provided in embodiments of the disclosure.

FIG. 11 is a diagram illustrating steps of a method for preparing a package structure provided in embodiments of the disclosure.

FIG. 12 is a flow chart of a method for preparing a photocatalytic layer provided in embodiments of the disclosure.

FIG. 13 is a diagram illustrating steps of a method for preparing a photocatalytic layer provided in embodiments of the disclosure.

Reference signs: 1—display apparatus, 10—display panel, 20—processor, 11—package structure, 12—light-emitting layer, 13—display surface, 111—first inorganic layer, 112—organic layer, 113—photocatalytic layer, 114—second inorganic layer, 121—light-emitting surface, 1131—photocatalytic material, 1132—co-catalyst, 1133—nanowire, 113a—precursor solution.

### DETAILED DESCRIPTION

The following will illustrate technical solutions of embodiments of the disclosure clearly and comprehensively with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

The terms “first”, “second”, and the like in the description, claims, and the above accompanying drawings of the present disclosure are used for distinguishing different objects, rather than for describing a specific order. In addition, the terms “include”, “have”, and any variations thereof are intended to cover non-exclusive inclusions. For example, a process, method, system, product, or apparatus that includes a series of steps or units is not limited to the listed steps or units, but optionally further includes steps or units not listed, or optionally further includes other steps or units inherent to the process, method, product, or apparatus.

Reference herein to “embodiment” or “implementation” means that a particular feature, structure, or characteristic described in connection with embodiments or implementations can be included in at least one embodiment of the present disclosure. The appearances of this phrase in various places in the description are not necessarily all referring to the same embodiment, nor are separate or alternative embodiments mutually exclusive of other embodiments. It is apparently and implicitly understood by those of ordinary skill in the art that the embodiments described herein can be combined with other embodiments.

Before describing a package structure 11, a method for preparing the package structure 11, a display panel 10, and a display apparatus 1 provided in embodiments of the disclosure, the related art will be introduced first in the following.

In the related art, organic light-emitting diode (OLED) refers to an organic semiconductor device, where an organic semiconductor material and a luminous material of the organic semiconductor device are caused to emit light by injection and recombination of carriers under an effect of an electric field. An OLED has a self-luminous property. The basic structure of the OLED includes a light-emitting layer on an indium tin oxides (ITO) glass, where the light-emitting layer is made from organic light-emitting material that has a thickness of dozens of nanometers, and a metal electrode layer of low work function is disposed on the light-emitting layer.

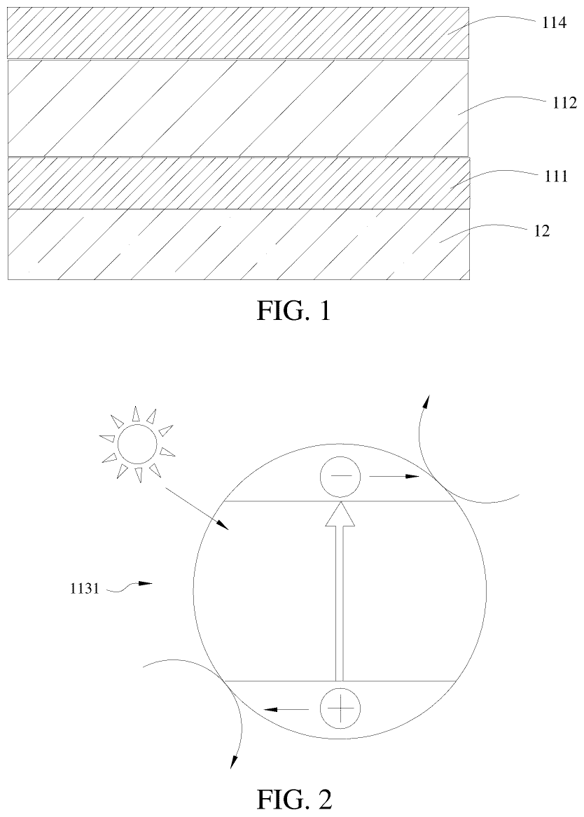

Reference is made to FIG. 1, which is a schematic view of a package structure provided in a comparative embodiment of the disclosure. The efficiency and service life of the OLED are closely related to the device structure. Currently, a “sandwich” structure is widely used, which refers to a structure in which a light-emitting layer is sandwiched between a cathode and an anode like a sandwich (one side is a transparent electrode so as to obtain a planar light-emitting effect). How to ensure a stable light emission of the device is a key problem to be solved for the commercialization of the OLED. Since organic materials of the OLED are very sensitive to substances such as water vapor and oxygen, an OLED device needs to be effectively packaged using various methods, so as to prevent the OLED device from being in contact with water vapor and oxygen, thereby reducing the aging rate of the OLED device and prolonging the service life of the OLED device. For a common display device product, a reliability test mainly simulates extreme usage conditions of the product, in which high temperature (60° C.) and high humidity (90%) are key indicators for testing the reliability of the device. In actual application, an environment with high humidity is more common than an oxygen-rich environment.

Photocatalysis technology refers to that a substance may undergo an oxidation-reduction reaction by using a semiconductor-based photocatalyst under a lighting condition. Currently, semiconductor-based photocatalytic water decomposition for generating hydrogen and photocatalytic reduction of carbon dioxide have become two major directions in the application of the photocatalysis technology. Common semiconductors that may be used as photocatalysts mainly include chalcogenide oxides, metal oxides, and organic semiconductor materials. Moreover, a co-catalyst carried on a surface of a semiconductor can significantly improve the photocatalytic efficiency.

Reference is made to FIG. 2, which is a schematic diagram illustrating a catalytic principle of a photocatalytic material provided in embodiments of the disclosure. Photocatalysis is a complex process including physical and chemical changes, and is simply a process in which some semiconductor-based photocatalytic materials undergo a series of reactions under the sunlight (ultraviolet light or visible light) to finally catalyze the decomposition of a substance. The reaction process may be divided into three parts. The first part is the generation of photo-induced carriers. If a semiconductor absorbs photon energy that is greater than the band gap after being exposed to the light, an electron (e⁻) will transit from a valence band of the semiconductor to a conduction band of the semiconductor, and a hole (h⁺) that is highly oxidative is created in the valence band, thereby generating a photo-induced electron-hole pair that is highly reactive inside the semiconductor. The second part is the migration of carriers. The photocatalytic reaction of the semiconductor actually occurs on a surface of the semiconductor. That is, an electron-hole pair generated inside the semiconductor is separated under the action of a built-in electric field or the action of a diffusional force, and is migrated from the inside of the semiconductor to the surface for reaction. The third part is that carriers participate in an oxidation-reduction reaction. When there is a defect or a trapping agent on the surface of the semiconductor, the recombination of the electron-hole pair is effectively suppressed, thereby accelerating the oxidation/reduction reaction of the photo-induced electro/hole on the surface of the semiconductor with target substances. Common semiconductor catalytic materials include semiconductor metal oxides such as titanium dioxide (TiO₂), zinc oxide (ZnO), tantalum pentoxide (Ta₂O₅), cadmium sulfide (CdS), and strontium titanate (SrTiO₃), sulfides, complex metal oxides, and the like. There are also some novel photocatalytic materials, such as perovskite type oxides, bismuth-based photocatalysts, molecular sieve photocatalysts, tungstate photocatalysts, halogen-oxide photocatalysts, and graphite-structured polymer photocatalytic materials.

In terms of the semiconductor-based photocatalytic water decomposition, after the photo-induced electron and the hole are diffused to the surface of a semiconductor material, a water molecule absorbed by the surface of the semiconductor material is oxidized by the hole in the valence band to produce H⁺ and O₂ and the dissociated H⁺ is reduced by the electron in the conduction band to produce hydrogen that will be released. As illustrated in FIG. 2, the reaction process is represented by the following equations:

semiconductor-based photocatalyst+hy→h⁺+e⁻;

2H₂O+4h⁺→4H⁺+O₂;

2H⁺+2e⁻→H₂;

overall reaction:semiconductor-based photocatalyst+hy+H₂O→H₂+½O₂.

The disclosure provides a package structure, so as to better package the OLED light-emitting layer to prevent water vapor intrusion.

It may be noted that, a package structure 11 provided in the disclosure may be applied not only to an OLED display panel 10, but also to a display panel 10 or a display device 1 having other types of function, all of which fall within the scope of protection of the disclosure, and the disclosure does not make any specific limitations in this regard.

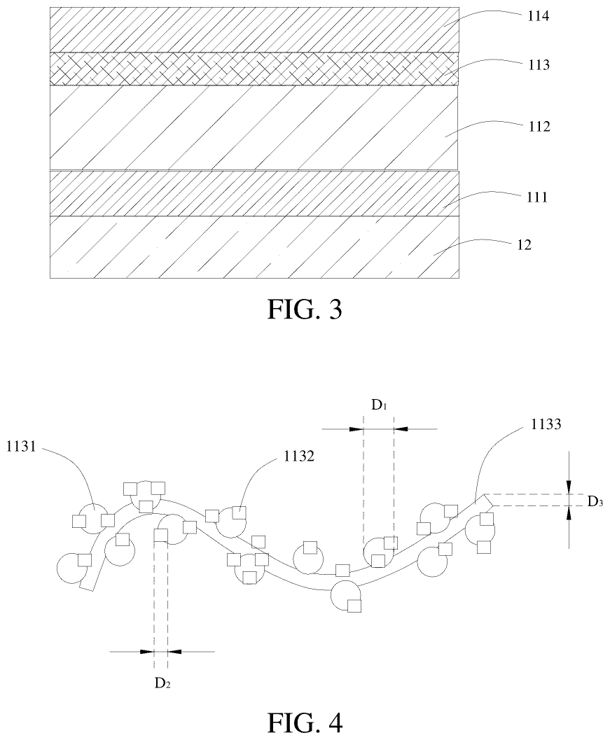

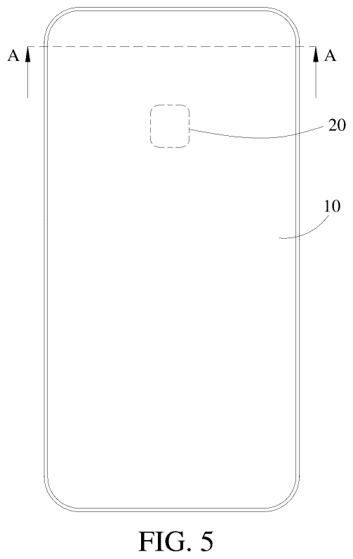

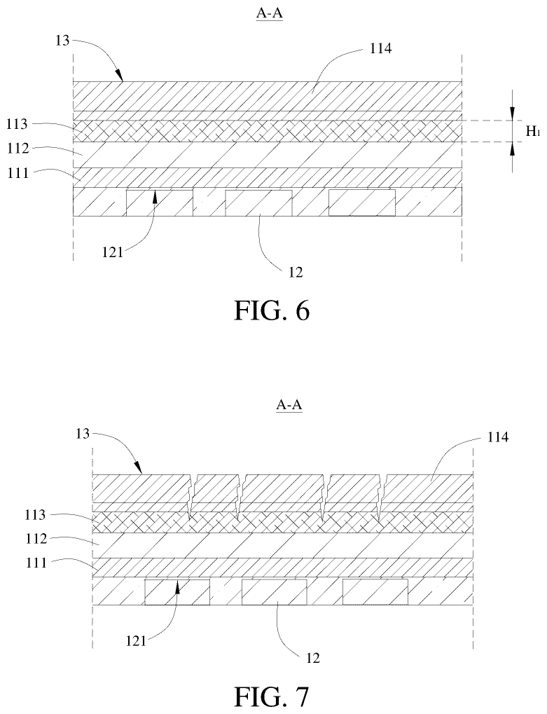

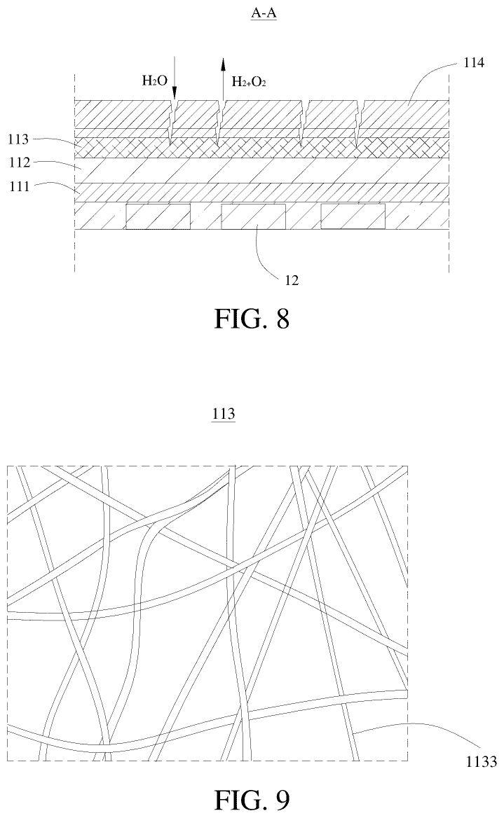

Reference is made to FIG. 3, FIG. 4, FIG. 5, FIG. 6, FIG. 7, and FIG. 8. FIG. 3 is a schematic cross-sectional structural view of a package structure provided in embodiments of the disclosure. FIG. 4 is a schematic structural view of a nanowire provided in embodiments of the disclosure. FIG. 5 is a schematic structural view of a display apparatus and a display panel provided in embodiments of the disclosure. FIG. 6 is a schematic cross-sectional structural view of the display panel provided in FIG. 5, taken along line A-A. FIG. 7 is a schematic structural view of a cracked package structure provided in embodiments of the disclosure. FIG. 8 is a schematic view illustrating a working principle of a package structure provide in embodiments of the disclosure. The disclosure provides the package structure 11, where the package structure includes a first inorganic layer 111, a photocatalytic layer 113, and a second inorganic layer 114 that are sequentially stacked. The photocatalytic layer 113 includes a photocatalytic material 1131 and a co-catalyst 1132. The photocatalytic material 1131 and the co-catalyst 1132 are used cooperatively to catalyze the decomposition of water vapor, the photocatalytic material 1131 includes graphitic carbon nitride (g-C₃N₄) particles, and the co-catalyst 1132 includes perylene tetracarboxylic acid (PTA).

Specifically, the package structure 11 may be applied to the OLED display panel 10, and is used to package and protect an organic light-emitting layer 12 in the OLED display panel 10, so as to prevent water vapor from invading the organic light-emitting layer 12. It may be understood that, in other embodiments of the disclosure, the package structure 11 may be applied to other types of display panels 10 or other electronic devices, and the application scenario of the package structure 11 should not constitute as a limitation on the package structure 11 provided in the embodiments.

In the embodiments of the disclosure, an example in which the package structure 11 covers a light-emitting surface 121 of the organic light-emitting layer 12 in the display panel 10 is used for illustration. It may be understood that, in other embodiments of the disclosure, the package structure 11 may be disposed on other components that need to be packaged and protected in the display panel 10, or may be disposed on a non-light-emitting surface 121 of the light-emitting layer 12, which may not be limited herein.

Optionally, in the embodiments of the disclosure, an example in which the display panel 10 is a flexible display panel 10 is used for illustration. That is, the package structure 11 may be a flexible package structure 10. It may be understood that, in other embodiments of the disclosure, the display panel 10 may be a non-flexible display panel 10.

The package structure 10 includes the first inorganic layer 111, the photocatalytic layer 113, and the second inorganic layer 114 that are sequentially stacked. Optionally, in the case where the package structure 10 is applied to the display panel 10, the first inorganic layer 111 may cover the light-emitting surface 121 of the light-emitting layer 12, the photocatalytic layer 113 is disposed on a side of the first inorganic layer 111 facing away from a light-emitting unit, and the second inorganic layer 114 may be disposed on a side of the photocatalytic layer 113 facing away from the first inorganic layer 111. In other words, the second inorganic layer 114 may be disposed adjacent to a display surface 13 of the display panel 10.

The photocatalytic layer 113 includes the photocatalytic material 1131 and the co-catalyst 1132, and the photocatalytic material 1131 and the co-catalyst 1132 are used cooperatively to catalyze the decomposition of water vapor. Specifically, in the case where the package structure 11 does not crack, the photocatalytic material 1131 is in a closed environment and cannot achieve a photocatalytic effect. In the case where the display panel 10 is subjected to repeated bending and the strength limit is reached, irregular cracks may be generated at the package structure 11. In the case where cracks penetrate through the second inorganic layer 114 located at the top and reach the photocatalytic layer 113, the photocatalytic material 1131 and the co-catalyst 1132 may be exposed. In the case where water vapor reaches the surface of the photocatalytic material 1131 and the surface of the co-catalyst 1132 through the cracks, the photocatalytic water decomposition for generating hydrogen occurs on the surface of the photocatalytic material 1131 under the irradiation of visible light. That is, water vapor will be decomposed into hydrogen (H₂) and oxygen (O₂), and H₂ and O₂ will be further discharged from the display panel 10 through the cracks, thereby avoiding further intrusion of water vapor, and thus effectively prolonging the service life of the display panel 10.

Optionally, the photocatalytic material 1131 consists of one or more of g-C₃N₄ particles, boron nitride (BN), ZnO, and TiO₂. It may be understood that, in other embodiments of the disclosure, the photocatalytic material 1131 may further include other materials with good photocatalytic performance.

Preferably, the photocatalytic material 1131 is the g-C₃N₄ particles. The g-C₃N₄ particles have good thermal stability and chemical stability. The g-C₃N₄ particles have stable performance at high temperatures, and the thermal stability of the g-C₃N₄ particles may start to be decreased only above 600° C. Furthermore, the g-C₃N₄ particles have stable performance in strong acids and strong bases. In addition, compared with a traditional TiO₂ photocatalyst, the g-C₃N₄ particles, as a novel non-metal photocatalytic material 1131, have a broader range of absorption spectrum and can achieve a photocatalytic effect under common visible light without the need of ultraviolet (UV) light. Therefore, in the embodiments, the g-C₃N₄ particles are selected as the photocatalytic material 1131, so that the package structure 11 may possess excellent stability and durability, and is applicable to a wider range of scenarios. Moreover, the photocatalytic layer 113 may possess highly catalytic efficiency, and can achieve rapid decomposition of water vapor, thereby guaranteeing a service life of components protected by the package structure 11.

Optionally, the co-catalyst 1132 may be PTA. For the g-C₃N₄ particles, the combination rate of photo-induced electrons and holes is high, which makes the photocatalytic activity difficult to be improved. In the embodiments, by using a PTA nanosheet as the co-catalyst 1132 for the g-C₃N₄ particles, the photocatalytic activity for generating hydrogen can be significantly improved, so that the package structure 11 can quickly decompose the invading water vapor to further prevent water vapor intrusion, and thus the erosion of the organic light-emitting layer 12 may be avoided. In this way, the service life of the display panel 10 is effectively prolonged, and the display panel 10 can maintain excellent display quality.

Preferably, the photocatalytic material 1131 is a transparent material, and the co-catalyst 1132 is a transparent material. The photocatalytic layer 113 has a transmittance T, where the transmittance T satisfies: T≥70%. In this way, the display quality of the display panel 10 may not be affected in the case where the package structure 11 is applied to the display panel 10.

Optionally, the material of the first inorganic layer 111 may include one or more of silicon oxide (SiO₂), silicon nitride (SiOₓN_{y}), and silicon nitride (SiNₓ). It may be understood that, the first inorganic layer 111 may be made from other materials, and the material of the first inorganic layer 111 should not constitute as a limitation on the package structure 11 provided in the embodiments.

Further optionally, the first inorganic layer 111 may be a transparent thin film.

Optionally, the material of the second inorganic layer 114 may include SiNₓ. It may be understood that, the second inorganic layer 114 may be made from other materials, and the material of the second inorganic layer 114 should not constitute as a limitation on the package structure 11 provided in the embodiments. Preferably, the second inorganic layer 114 is a SiNₓ thin film with high compactness, which may achieve a good passivation effect, thereby effectively preventing the intrusion of external water vapor.

Further optionally, the second inorganic layer 114 may be a transparent thin film.

It may be understood that, in the case where the display panel 10 is a flexible and bendable panel, a side of the display panel 10 adjacent to the display surface 13 is prone to crack as the second inorganic layer 114 has strong rigidity. The photocatalytic layer 113 is disposed on a side of the second inorganic layer 114 facing away from the display surface 13. In this way, in the case where cracks are generated at the display panel 10, the photocatalytic layer 113 can effectively absorb water vapor invading through the cracks, thereby effectively prolonging the service life of the display panel 10.

Optionally, the package structure 11 may further include an organic layer 112, and the organic layer 112 is sandwiched between the second inorganic layer 114 and the photocatalytic layer 113. The organic layer 112 can not only prevent inorganic films from cracking and release the stress between inorganic materials, but also improve the flexibility of the entire package structure 11, thereby realizing a reliable flexible package. Moreover, the photocatalytic layer 113 is disposed on a side of the organic layer 112 adjacent to the display surface 13 of the display panel 10, so that the photocatalytic layer 113 may protect the organic layer 112 from the erosion of water vapor.

Further optionally, the material of the organic layer 112 may include one or more of polymethyl methacrylate (PMMA) and resin. It may be understood that, the organic layer 112 may be made from other materials.

In conclusion, the package structure 11 provided in embodiments of the disclosure includes the first inorganic layer 111, the photocatalytic layer 113, and the second inorganic layer 114 that are sequentially stacked. The photocatalytic layer 113 includes the photocatalytic material 1131 and the co-catalyst 1132. The photocatalytic material 1131 and the co-catalyst 1132 are used cooperatively to catalyze the decomposition of water vapor. As such, in the case where cracks are generated at the package structure 11, water vapor invading through the cracks is decomposed and consumed through an oxidation-reduction reaction, and then decomposition products are respectively discharged. In this way, damage of water vapor intrusion under an environment with high humidity to the components of the display panel 10 may be minimized, and accordingly the stability of the performance of the display panel 10 may be improved. The photocatalytic material 1131 includes the g-C₃N₄ particles and the co-catalyst 1132 includes the PTA, so that the package structure 11 possesses excellent stability and durability, which is applicable to a wider range of scenarios, and the photocatalytic layer 113 possesses high catalytic efficiency, which can achieve rapid decomposition on water vapor. In this way, the service life of the display panel 10 is prolonged, and the display panel 10 can maintain excellent display quality.

Reference is made to FIG. 4 again. Each of the g-C₃N₄ particles has a particle diameter range D₁, and the particle diameter range D₁ satisfies: 100 nm≤D₁≤10000 nm.

Optionally, the particle diameter range D₁ may be understood as the average particle size of the g-C₃N₄ particles. Optionally, the particle diameter range D₁ may be understood as the maximum length size of the g-C₃N₄ particles.

Optionally, the particle diameter range D₁ of the g-C₃N₄ particles may be but is not limited to 100 nm, 200 nm, 500 nm, 1000 nm, 2000 nm, 3000 nm, or other values, as long as the particle diameter range D₁ satisfies: 100 nm≤D₁≤10000 nm. A relatively small particle diameter of the g-C₃N₄ particles may lead to high precision requirement for the preparation process, and may increase the production cost of the package structure 11. A relatively large particle diameter of the g-C₃N₄ particles may lead to fewer exposed active sites compared to the g-C₃N₄ particles with a proper particle diameter, in the case where the photocatalytic layers 113 contain the same content of the g-C₃N₄ particles. Therefore, the catalytic efficiency is low, which is unfavorable for rapid decomposition of water vapor by the package structure 11.

Preferably, the thickness of the g-C₃N₄ particles may range from 2 nm to 10 nm.

In the embodiments, the particle diameter range D₁ of the g-C₃N₄ particles satisfies: 100 nm≤D₁≤10000 nm, and the thickness of the g-C₃N₄ particles preferably ranges from 2 nm to 10 nm. In this case, the g-C₃N₄ particles are easy to be prepared and may possess a large number of catalytic active sites, so that the photocatalytic layer 113 has a high catalytic efficiency. Furthermore, in the case where cracks are generated at the package structure 11, the nanoscale g-C₃N₄ particles may be densely and evenly distributed in the photocatalytic layer 113, which makes the g-C₃N₄ particles to be exposed to the environment with greater probability and to rapidly decompose the invading water vapor. Since the particle diameter of the g-C₃N₄ particle is relatively small, the package structure 11 may possess good light transmittance.

Optionally, the g-C₃N₄ particles may be prepared from a variety of nitrogen-rich precursors such as dicyandiamide, urea, melamine, thiourea, and the like. The g-C₃N₄ particles may also be prepared by a variety of physical/chemical preparation means.

Further optionally, as the g-C₃N₄ particles required in the embodiments are nanoscale particles and the requirement for uniformity of the g-C₃N₄ particles is relatively high, a solid phase method may be used for preparation. In this preparation method, a compound having a triazine structure is generally selected as a reaction precursor, such as cyanuric chloride, melamine, and the like. LiN3, NaN3, and the like are used as nitrogen sources. The solid phase reaction is performed at a certain temperature to prepare the g-C₃N₄ particles. By using this method, the carbon-to-nitrogen ratio (C/N ratio) may be adjusted flexibly, and the nanostructure and morphology of the material may be controlled.

Further optionally, the g-C₃N₄ particles may be prepared by thermal polymerization. In a thermal polymerization reaction to prepare the g-C₃N₄ particles, precursors are thermally induced and further undergo condensation to prepare the g-C₃N₄ particles. As a direct and simple preparation method, thermal polymerization has gradually become a common and important synthetic method for preparing the g-C₃N₄ particles in recent years, which is widely used for preparing a g-C₃N₄ particles-based catalyst, a catalyst carrier, an energy storage material, and the like. It may be understood that, the g-C₃N₄ particles may be prepared by other preparation methods, and the preparation method of the g-C₃N₄ particles should not constitute as a limitation to the package structure 11 provided in the embodiments.

Reference is made to FIG. 4 again. The PTA is a PTA nanosheet, and the PTA nanosheet has a maximum width D₂. The maximum width D₂ satisfies: 50 nm≤D₂≤2000 nm.

Specifically, the PTA nanosheet may be used as the co-catalyst 1132 for the g-C₃N₄ particles. When the PTA nanosheet is attached to the surface of the g-C₃N₄ particles, the photocatalytic activity of the g-C₃N₄ particles may be significantly improved, and thus the efficiency of decomposing water vapor by the photocatalytic layer 113 is greatly improved.

Optionally, the maximum width D₂ may be understood as a maximum distance between any two points of the PTA nanosheet.

Optionally, the maximum width D₂ may be, but is not limited to, 50 nm, 100 nm, 200 nm, 300 nm, 500 nm, 800 nm, 1000 nm, 1200 nm, 1500 nm, 1800 nm, 2000 nm, or other values, as long as the maximum width D₂ satisfies: 50 nm≤D₂≤2000 nm.

Preferably, the thickness of the PTA nanosheet may range from 0.5 nm to 1.5 nm.

It may be understood that, a relatively small maximum width of the PTA nanosheet may lead to high requirement on the experimental accuracy, which is unfavorable for industrial mass production, and results in too high cost of the package structure 11. A relatively large maximum width of the PTA nanosheet may lead to a poor co-catalytic performance of the PTA nanosheet, which makes the catalytic performance of the photocatalytic layer 113 difficult to meet requirements.

In the embodiments, the maximum width D₂ of the PTA nanosheet satisfies: 50 nm≤D₂≤2000 nm. In this way, the preparation of the PTA nanosheet may be easily achieved, the PTA nanosheet has a relatively high reactivity and can provide more reactive sites, thereby effectively improving the photocatalytic activity of the g-C₃N₄ particles. As a result, the g-C₃N₄ particles can efficiently decompose the invading water vapor.

Optionally, in the photocatalytic layer 113, a mass ratio of the PTA to the g-C₃N₄ particles ranges from 0.05:1 to 0.15:1. and in the photocatalytic layer 113, a mass percentage of the g-C₃N₄ particles ranges from 1% to 2%, and a mass percentage of the PTA ranges from 0.05% to 0.3%.

Optionally, the mass ratio of the PTA to the g-C₃N₄ particles may be, but is not limited to 0.05:1, 0.06:1, 0.07:1, 0.08:1, 0.09:1, 0.1:1, 0.11:1, 0.12:1, 0.13:1, 0.14:1, 0.15:1, or other ratios, as long as the mass ratio ranges from 0.05:1 to 0.15:1.

It may be understood that, a relatively small mass ratio of the PTA to the g-C₃N₄ particles may lead to a weak co-catalytic effect on the g-C₃N₄ particles by the PTA. In this case, the photocatalytic performance of the g-C₃N₄ particles cannot be effectively improved, the photocatalytic layer 113 cannot rapidly decompose the invading water vapor, and the package structure 11 cannot provide good protection. A relatively large mass ratio of the PTA to the g-C₃N₄ particles may lead to aggregation of the PTA, and followed by sedimentation of the PTA. In this case, the total specific surface area of the PTA is reduced, the effective contact area between the PTA and the g-C₃N₄ particles is reduced, and thus the catalytic efficiency is reduced.

In the embodiments, the mass ratio of the PTA to the g-C₃N₄ particles ranges from 0.05:1 to 0.15:1, so that the PTA can effectively improve the photocatalytic performance of the g-C₃N₄ particles without causing the aggregation and the sedimentation of the PTA due to large mass percentage of the PTA, thereby ensuring that the effective contact area between the PTA and the g-C₃N₄ particles is sufficient to possess high photocatalytic efficiency. In the case where cracks are generated at the package structure 11, the photocatalytic layer 113 can rapidly decompose the invading water vapor to prevent further intrusion of water vapor, thereby effectively protecting the organic light-emitting layer 12 from being eroded by water vapor. In this way, the package structure 11 can better protect the display panel 10 and effectively prolong the service life of the display panel 10.

Reference is made to FIG. 4 and FIG. 9. FIG. 9 is a partially schematic structural view of a photocatalytic layer provided in embodiments of the disclosure. The photocatalytic layer 113 further includes multiple nanowires 1133. The multiple nanowires 1133 are arranged in a staggered manner, the g-C₃N₄ particles are carried by the nanowires 1133, and the PTA is carried by at least one of the nanowires 1133 or the g-C₃N₄ particles.

Optionally, the material of the nanowires 1133 may be polyacrylonitrile (PAN), in other words, the nanowires 1133 may be PAN nanofibers. It may be understood that, in other embodiments of the disclosure, the nanowires 1133 may be made from other material, such as polyvinyl pyrrolidone (PVP), polyvinyl alcohol (PVA), and the like.

Further optionally, with the PAN as a precursor solution, the nanowires 1133 may be prepared through an electrostatic spinning.

Optionally, the photocatalytic layer 113 includes multiple nanowires 1133, and the number of the nanowires 1133 may be but is not limited to two, three, ten, one hundred, one thousand, or other numbers. The multiple nanowires 1133 are arranged in a staggered manner. Specifically, the multiple nanowires 1133 may be prepared through the electrostatic spinning and may be formed as a material similar to a fiber membrane.

Optionally, the multiple nanowires 1133 may be the matrix material of the photocatalytic layer 113, and the multiple nanowires 1133 may be arranged in a staggered manner and overlapped with each other to form a three-dimensional fiber membrane structure, so that the photocatalytic layer 113 may be formed as an organic felt-like membrane with good ductility.

Further optionally, by uniformly dispersing the g-C₃N₄ particles and the PTA nanosheet in the PAN precursor solution and performing the electrostatic spinning, a photocatalytic membrane is prepared. It may be understood that, the preparation process of the photocatalytic membrane may further include other processes, such as a heat treatment, an impurity removal treatment, and the like, which may not be limited herein.

Optionally, the g-C₃N₄ particles are carried by the nanowires 1133, which may be understood as that at least part of the g-C₃N₄ particles are attached to the surface of the nanowires 1133. The PTA is carried by at least one of the nanowires 1133 or the g-C₃N₄ particles, which may be understood as that there may be a part of the PTA attached to the surface of the nanowires 1133, and there may be a part of the PTA attached to the surface of the g-C₃N₄ particles. In other embodiments of the disclosure, all or most of the PTA may be attached to the surface of the g-C₃N₄ particles, and thus the photocatalytic efficiency of the g-C₃N₄ particles is effectively improved.

In the embodiments, the PAN nanowires 1133 are used as carriers for the g-C₃N₄ particles and the PTA. In this way, the photocatalytic layer 113 may be an organic felt-like membrane with good ductility, so that the ductility of the package structure 11 may be effectively improved, and the package structure 11 may possess a certain degree of bending resistance. Moreover, the photocatalytic membrane may be used as a toughness enhancement layer of the package structure 11, thereby further improving the durability of the package structure 11 and the display panel 10.

Reference is made to FIG. 4 again. Each of the nanowires 1133 has a diameter range D₃, and the diameter range D₃ satisfies: 0.5 μm≤D₃≤1.5 μm.

Optionally, the diameter range D₃ may be understood as the average diameter of the nanowires 1133 in cross-section.

Optionally, the diameter range D₃ may be, but is not limited to, 0.5 μm, 0.7 μm, 0.8 μm, 1 μm, 1.2 μm, 1.3 μm, 1.5 μm, or other values, as long as the diameter range D₃ satisfies: 0.5 μm≤D₃≤1.5 μm.

It may be understood that, a relatively small diameter range of the nanowires 1133 may lead to a lack of toughness of the photocatalytic layer 113, resulting in that the package structure 11 is prone to crack when the package structure 11 is bent and fails to provide good package protection. A relatively large diameter range of the nanowires 1133 may lead to a small specific surface area and a low porosity of the nanowires 1133, which is unfavorable for the nanowires 1133 to attach to the g-C₃N₄ particles, and is unfavorable for an evenly distribution of the g-C₃N₄ particles in the photocatalytic layer 113.

In the embodiments, the diameter range D₃ of the nanowires 1133 satisfies: 0.5 μm≤D₃≤1.5 μm. In this way, the photocatalytic layer 113 possesses good toughness and ductility, so that the mechanical performance of the package structure 11 is improved, and thus the package structure 11 may possess good bending resistance. Moreover, when the diameter range D₃ satisfies the above range, the photocatalytic layer 113 may have a high specific surface area and a high porosity, and the nanowire 1133 attached to the g-C₃N₄ particles may be evenly and densely distributed in the photocatalytic layer 113. In this way, there is a chance for all the g-C₃N₄ particles to be exposed in the case where the package structure 11 cracks at various positions, and thus the invading water vapor may be effectively decomposed, thereby improving the protection for the package structure 11.

Reference is made to FIG. 6 again. The photocatalytic layer 113 has a thickness range H₁ in a direction in which the first inorganic layer 111 and the photocatalytic layer 113 are stacked, and the thickness range H₁ satisfies: 1 μm≤H₁≤3 μm.

Optionally, the thickness range H₁ may be understood as a largest height of the photocatalytic layer 113 in the direction in which the first inorganic layer 111 and the photocatalytic layer 113 are stacked. The thickness range H₁ may alternatively be understood as an average height of the photocatalytic layer 113 in the direction in which the first inorganic layer 111 and the photocatalytic layer 113 are stacked.

Optionally, the thickness range H₁ may be, but is not limited to 1 μm, 1.5 μm, 2 μm, 2.5 μm, 3 μm, or other values, as long as the thickness range H₁ satisfies: 1 μm≤H₁≤3 μm. A relatively small thickness range H₁ may lead to that the photocatalytic layer 113 can only decompose a small amount of water vapor in the case where cracks are generated at the package structure 11, resulting in that water vapor still has the chance to erode the organic light-emitting layer 12. A relatively large thickness range H₁ may lead to a relatively large thickness of the package structure 11, which is unfavorable for the lightweight design requirement of the display panel 10 in the case where the package structure 11 is applied to the display panel 10.

In the embodiments, the thickness range H₁ of the photocatalytic layer 113 satisfies: 1 μm≤H₁≤3 μm. In this case, the photocatalytic layer 113 may decompose the invading water vapor efficiently to protect the organic light-emitting layer 12 from being eroded, while take into account the lightweight design requirement of the package structure 11 and the display panel 10.

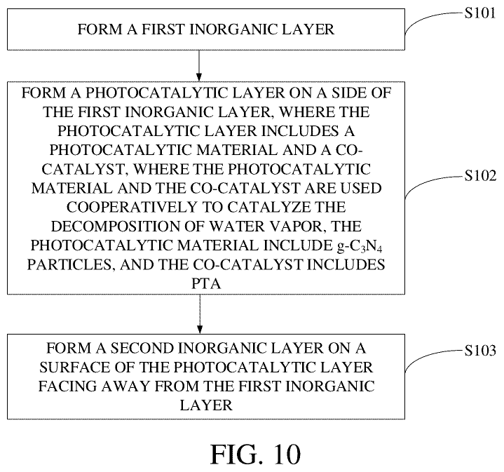

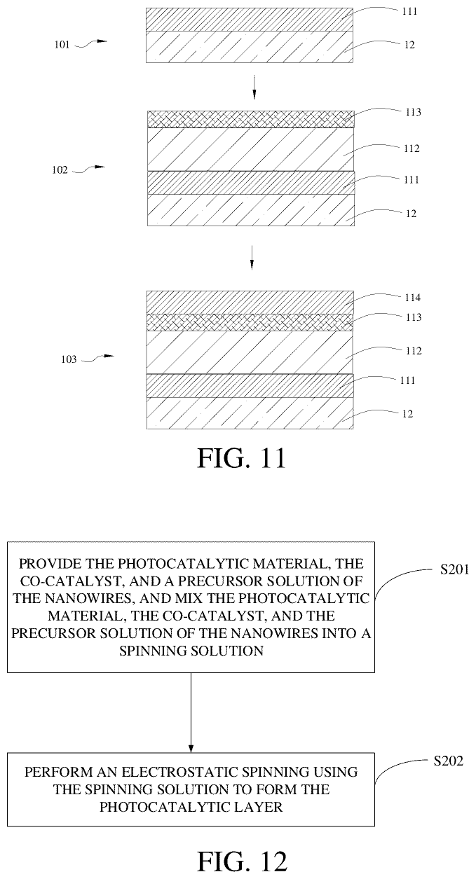

Reference is made to FIG. 10 and FIG. 11. FIG. 10 is a flow chart of a method for preparing a package structure provided in embodiments of the disclosure. FIG. 11 is a diagram illustrating steps of a method for preparing a package structure provided in embodiments of the disclosure. The disclosure further provides a preparation method for the package structure 11. The preparation method includes S101, S102, and S103 as follows.

At S101, a first inorganic layer 111 is formed.

Specifically, the first inorganic layer 111 may be prepared by, but is not limited to, a process of plasma-enhanced chemical vapor deposition (PECVD).

Optionally, the material of the first inorganic layer 111 may include one or more of SiO₂, SiOₓN_{y}, and SiNₓ.

Optionally, in embodiments of the disclosure, in the case where the package structure 11 is applied to the display panel 10, the first inorganic layer 111 may cover the organic light-emitting layer 12, and the first inorganic layer 111 may be prepared directly on a side of the organic light-emitting layer 12, or may be prepared on a substrate first and then transferred to the surface of the organic light-emitting layer 12.

Optionally, the thickness of the first inorganic layer 111 may range from 1 m to 2 m.

At S102, form a photocatalytic layer 113 on a side of the first inorganic layer 111, where the photocatalytic layer 113 includes a photocatalytic material 1131 and a co-catalyst 1132, where the photocatalytic material 1131 and the co-catalyst 1132 are used cooperatively to catalyze the decomposition of water vapor, the photocatalytic material 1131 includes g-C₃N₄ particles, and the co-catalyst 1132 includes PTA.

Optionally, an organic layer 112 is firstly formed on a side of the first inorganic layer 111, and the photocatalytic layer 113 is formed on a surface of the organic layer 112 facing away from the first inorganic layer 111.

Optionally, the material of the organic layer 112 may include one or more of PMMA and resin.

Optionally, the thickness of the organic layer 112 may range from 10 μm to 30 μm. Specifically, in the case where the package structure 11 is used to package the organic light-emitting layer 12 of the display panel 10, although the first inorganic layer 111 can cover pinholes on a metal layer of the display panel 10 (in the process of preparing a large-size flexible OLED display panel 10, some unavoidable small protruding particles may appear on the surface of the film layer before the coating of the cathode; as the cathode metal layer is very thin, the small protruding particles are able to pierce the cathode to form pinholes in the cathode metal layer, resulting in that water vapor and oxygen enter the device through the pinholes to damage the display panel 10), new pinholes may be generated on the first inorganic layer 111. In this case, covering one organic layer 112 with the thickness of 10 to 30 μm to flatten the interface can effectively fill the defects on the first inorganic layer 111, thereby extending the diffusion path for water vapor and oxygen to enter the organic light-emitting layer 12 and effectively improving the bending resistance of the organic layer 112.

Optionally, the photocatalytic layer 113 covers a surface of the organic layer 112 facing away from the first inorganic layer 111. Methods of covering the photocatalytic layer 113 on the organic layer 112 may be pasting, organic curing, and the like.

Optionally, the photocatalytic material 1131 may be the g-C₃N₄ particles.

Optionally, the co-catalyst 1132 may be the PTA nanosheet.

At S103, form a second inorganic layer 114 on a surface of the photocatalytic layer 113 facing away from the first inorganic layer 111.

Optionally, the second inorganic layer 114 may be prepared by, but is not limited to, a process of PECVD.

Optionally, the material of the second inorganic layer 114 may include SiNₓ.

Optionally, the thickness of the second inorganic layer 114 may range from 2 μm to 3 μm.

Specifically, the photocatalytic layer 113 (g-C₃N₄/PAN thin film) is of a felt shape, that is, the photocatalytic layer 113 is porous in the case where the PAN nanowires 1133 are selected as the carriers. In the case where the second inorganic layer 114 (SiNₓ) is deposited on the surface of the photocatalytic layer 113 facing away from the first inorganic layer 111 during the process of PECVD, the SiNₓ material may be deposited in pores of the photocatalytic layer 113 to form a SiNₓ+g-C₃N₄/PAN film layer, and the SiNₓ+g-C₃N₄/PAN film layer may achieve a photocatalytic effect. Since the SiNₓ+g-C₃N₄/PAN film layer includes the organic nanowires 1133, the ductility of the SiNₓ+g-C₃N₄/PAN film layer is better than the ductility of a pure SiNₓ inorganic film, which may improve the ductility of inorganic film layers at the surface of the package structure 11 in a certain extent. When the amount of deposit completely covers the felt-like photocatalytic thin film and is higher than the felt-like photocatalytic thin film, the SiNₓ thin film that is further deposited becomes an inorganic thin film with good compactness. That is, the second inorganic layer 114 is formed. The SiNₓ thin film with good compactness has a good passivation effect, which may effectively prevent the entering of external water vapor.

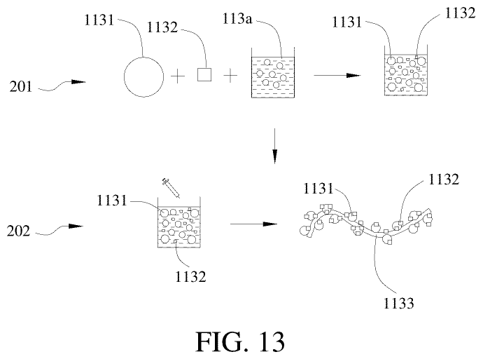

Reference is made to FIG. 12 and FIG. 13. FIG. 12 is a flow chart of a method for preparing a photocatalytic layer provided in embodiments of the disclosure. FIG. 13 is a diagram illustrating steps of a method for preparing a photocatalytic layer provided in embodiments of the disclosure. The photocatalytic layer 113 further includes multiple nanowires 1133 arranged in a staggered manner. The operation of forming the photocatalytic layer 113 on the side of the first inorganic layer 111 includes S201 and S202 as follows.

At S201, provide the photocatalytic material 1131, the co-catalyst 1132, and a precursor solution 113a of the nanowires 1133, and mix the photocatalytic material 1131, the co-catalyst 1132, and the precursor solution 113a of the nanowires 1133 into a spinning solution.

Optionally, the g-C₃N₄ particles and the PTA are evenly dispersed in a PAN precursor solution 113a to form the spinning solution.

Further optionally, the g-C₃N₄ particles and the PTA may be evenly dispersed in the PAN precursor solution 113a through methods such as, but not limited to, centrifugal stirring, ultrasonic oscillation, and the like, which may not be limited herein.

At 202, perform an electrostatic spinning using the spinning solution to form the photocatalytic layer 113.

Optionally, the electrostatic spinning is performed using the PAN precursor solution 113a that is mixed with the g-C₃N₄ particles and the PTA, to obtain a fiber membrane carrying the g-C₃N₄ particles and the PTA, with the PAN nanowires 1133 as the matrix. That is, the photocatalytic layer 113 is formed. The photocatalytic layer 113 prepared by the electrostatic spinning possesses good toughness and ductility, which may improve the mechanical property of the package structure 11.

Optionally, parameters such as electric field strength, flow rate, distance from a spinneret to a receiving pole plate and environmental parameters (temperature, humidity, and air flow in the operation box) during the electrostatic spinning process may be adjusted according to the actual needs of the photocatalytic layer 113, which will not be limited herein.

Reference is made to FIG. 5 and FIG. 6 again. The disclosure further provides a display panel 10. The display panel 10 includes a light-emitting layer 12 and the package structure 11. The light-emitting layer 12 has a light-emitting surface 121 configured to emit light. The package structure 11 covers the light-emitting surface 121 of the light-emitting layer 12, and the first inorganic layer is closer to the light-emitting layer 12 than the second inorganic layer 114.

Optionally, the display panel 10 may be a OLED display panel 10. Furthermore, the OLED display panel 10 may be, but is not limited to, a passive matrix OLED display panel 10, an active matrix OLED display panel 10, a transparent OLED display panel 10, a top-illuminated OLED display panel 10, a foldable OLED display panel 10, a white-light OLED display panel 10, and the like. It may be understood that, in other embodiments of the disclosure, the display panel 10 may be of other types, and the type of the display panel 10 should not constitute as a limitation on the display panel 10 provided in the embodiments.

Optionally, the light-emitting layer 12 may be the organic light-emitting layer 12. The material of the light-emitting layer 12 may be, but is not limited to, a small molecule organic fluorescent substance, a phosphorescent substance, a polymer, and the like.

Optionally, the light-emitting layer 12 has the light-emitting surface 121 configured to emit light. The light emitting direction of the light-emitting layer 12 may be, but is not limited to, a direction in which the light-emitting layer 12 points toward the package structure 11.

Further optionally, in an embodiment of the disclosure, the display panel 10 may be flexible and bendable. The package structure 11 may cover the light-emitting surface 121 of the light-emitting layer 12 to package the light-emitting layer 12. In this way, the light-emitting layer 12 may be protected from the erosion of water vapor and oxygen when the display panel 10 is bent.

Further optionally, in another embodiment of the disclosure, the display panel 10 may be packaged by a non-flexible packaging method. The photocatalytic material 1131 may be disposed on edges of the package structure 11 that are susceptible to the entering of water vapor. For example, for a rigid packaged display panel 10, diffusion paths of water vapor are normally located at an edge of the display panel 10. Therefore, the photocatalytic material 1131 may be disposed on the edge.

In the embodiments, the package structure 11 provided in embodiments of the disclosure includes the first inorganic layer 111, the photocatalytic layer 113, and the second inorganic layer 114 that are sequentially stacked. The photocatalytic layer 113 includes the photocatalytic material 1131 and the co-catalyst 1132. The photocatalytic material 1131 and the co-catalyst 1132 are used cooperatively to catalyze the decomposition of water vapor. As such, in the case where cracks are generated at the package structure 11, water vapor invading through the cracks is decomposed and consumed through an oxidation-reduction reaction, and then decomposition products are respectively discharged. In this way, damage of water vapor intrusion under an environment with high humidity to the components of the display panel 10 may be minimized, and accordingly the stability of the performance of the display panel 10 may be improved. The photocatalytic material 1131 includes the g-C₃N₄ particles and the co-catalyst 1132 includes the PTA, so that the package structure 11 possesses excellent stability and durability, which is applicable to a wider range of scenarios, and the photocatalytic layer 113 possesses high catalytic efficiency, which can achieve rapid decomposition on water vapor. In this way, the service life of the display panel 10 is prolonged, and the display panel 10 can maintain excellent display quality.

Reference is made to FIG. 5 and FIG. 6 again. The disclosure further provides a display apparatus 1, which includes a processor 20 and the display panel 10. The processor 20 is electrically connected to the display panel 10 and is configured to control the display panel 10 to display images.

Optionally, the display apparatus 1 may be, but is not limited to, a cellphone, a mirror, a glass, a tablet, a laptop, a personal computer (PC), a pocket PC, a personal digital assistant (PDA), a portable media player (PMP), a navigation device, a wearable device, a smart bracelet, a pedometer, or any other devices with a display function.

Optionally, the processor 20 may include an integrated circuit (IC). The processor 20 may be, but is not limited to, electrically connected to the display panel 10 directly, or electrically connected to the display panel 10 indirectly. The processor 20 may be configured to control the opening or closing of the display panel 10, and may be configured to control image display of the display panel 10.

In the embodiments, the display panel 10 is applied to the display apparatus 1, which can prevent water vapor from invading the display apparatus 1, thereby effectively prolonging the service life of the display apparatus 1. Moreover, the display effect of the display apparatus 1 may be maintained and the reliability of the display apparatus 1 may be effectively improved.

The terms of “embodiment” and “implementation” mentioned in the present disclosure means that the specific features, structures, or characteristics described with reference to the embodiments may be encompassed in at least one embodiment of the present disclosure. The phrase at various locations in the specification does not necessarily refer to the same embodiment, or an independent or alternative embodiment exclusive of another embodiment. Those skilled in the art may understand explicitly and implicitly that the embodiments described in the present disclosure may be combined with other embodiments. In addition, it may also be understood that the features, structures or characteristics described in the embodiments of the present disclosure may be combined as desired to obtain embodiments without departing from the spirit and scope of the technical solution of the present disclosure if there is no contradiction between the embodiments.

Finally, it may be noted that the above implementations are merely used for illustrating rather than limiting the technical solutions of the present disclosure; and although the present disclosure has been described in detail with reference to the preferred implementations, those skilled in the art may understand that modifications or equivalent substitutions may be made to the technical solutions of the present disclosure without departing from the spirit and scope of the technical solutions of the present disclosure.

What is claimed is:

1. A package structure, comprising:
a first inorganic layer, a photocatalytic layer, and a second inorganic layer that are sequentially stacked, wherein the photocatalytic layer comprises a photocatalytic material and a co-catalyst, wherein the photocatalytic material and the co-catalyst are used cooperatively to catalyze decomposition of water vapor, the photocatalytic material comprises graphitic carbon nitride (g-C₃N₄) particles, and the co-catalyst comprises perylene tetracarboxylic acid (PTA).

2. The package structure of claim 1, wherein each of the g-C₃N₄ particles has a particle diameter range D₁, wherein the particle diameter range D₁ satisfies: 100 nm≤D₁≤10000 nm.

3. The package structure of claim 1, wherein the PTA is a PTA nanosheet, wherein the PTA nanosheet has a maximum width D₂, and the maximum width D₂ satisfies: 50 nm≤D₂≤2000 nm.

4. The package structure of claim 1, wherein a mass ratio of the PTA to the g-C₃N₄ particles ranges from 0.05:1 to 0.15:1; and
in the photocatalytic layer, a mass percentage of the g-C₃N₄ particles ranges from 1% to 2%, and a mass percentage of the PTA ranges from 0.05% to 0.3%.

5. The package structure of claim 1, wherein the photocatalytic layer further comprises a plurality of nanowires, wherein the plurality of nanowires are arranged in a staggered manner, the g-C₃N₄ particles are carried by the nanowires, and the PTA is carried by at least one of the nanowires or the g-C₃N₄ particles.

6. The package structure of claim 5, wherein each of the nanowires has a diameter range D₃, wherein the diameter range D₃ satisfies: 0.5 μm≤D₃≤1.5 μm.

7. The package structure of claim 1, wherein the photocatalytic layer has a thickness range H₁ in a direction in which the first inorganic layer and the photocatalytic layer are stacked, wherein the thickness range H₁ satisfies: 1 μm≤H₁≤3 μm.

8. A preparation method for a package structure, comprising:
forming a first inorganic layer;
forming a photocatalytic layer on a side of the first inorganic layer, wherein the photocatalytic layer comprises a photocatalytic material and a co-catalyst, wherein the photocatalytic material and the co-catalyst are used cooperatively to catalyze decomposition of water vapor, the photocatalytic material comprises graphitic carbon nitride (g-C₃N₄) particles, and the co-catalyst comprises perylene tetracarboxylic acid (PTA); and
forming a second inorganic layer on a surface of the photocatalytic layer facing away from the first inorganic layer.

9. The preparation method of claim 8, wherein the photocatalytic layer further comprises a plurality of nanowires arranged in a staggered manner, and wherein forming the photocatalytic layer on the side of the first inorganic layer comprises:
providing the photocatalytic material, the co-catalyst, and a precursor solution of the nanowires, and mixing the photocatalytic material, the co-catalyst, and the precursor solution of the nanowires into a spinning solution; and
performing an electrostatic spinning using the spinning solution to form the photocatalytic layer.

10. A display panel, comprising:
a light-emitting layer, wherein the light-emitting layer has a light-emitting surface configured to emit light; and
a package structure, wherein the package structure comprises a first inorganic layer, a photocatalytic layer, and a second inorganic layer that are sequentially stacked, wherein the photocatalytic layer comprises a photocatalytic material and a co-catalyst, wherein the photocatalytic material and the co-catalyst are used cooperatively to catalyze decomposition of water vapor, the photocatalytic material comprises graphitic carbon nitride (g-C₃N₄) particles, and the co-catalyst comprises perylene tetracarboxylic acid (PTA);
wherein the package structure covers the light-emitting surface of the light-emitting layer, and the first inorganic layer is closer to the light-emitting layer than the second inorganic layer.

11. The display panel of claim 10, wherein each of the g-C₃N₄ particles has a particle diameter range D₁, wherein the particle diameter range D₁ satisfies: 100 nm≤D₁≤10000 nm.

12. The display panel of claim 10, wherein the PTA is a PTA nanosheet, wherein the PTA nanosheet has a maximum width D₂, and the maximum width D₂ satisfies: 50 nm≤D₂≤2000 nm.

13. The display panel of claim 10, wherein a mass ratio of the PTA to the g-C₃N₄ particles ranges from 0.05:1 to 0.15:1; and
in the photocatalytic layer, a mass percentage of the g-C3N4 particles ranges from 1% to 2%, and a mass percentage of the PTA ranges from 0.05% to 0.3%.

14. The display panel of claim 10, wherein the photocatalytic layer further comprises a plurality of nanowires, wherein the plurality of nanowires are arranged in a staggered manner, the g-C₃N₄ particles are carried by the nanowires, and the PTA is carried by at least one of the nanowires or the g-C₃N₄ particles.

15. The display panel of claim 14, wherein each of the nanowires has a diameter range D₃, wherein the diameter range D₃ satisfies: 0.5 μm≤D₃≤1.5 μm.

16. The display panel of claim 10, wherein the photocatalytic layer has a thickness range H₁ in a direction in which the first inorganic layer and the photocatalytic layer are stacked, wherein the thickness range H₁ satisfies: 1 μm≤H₁≤3 μm.
